(19) United States
(12) Patent Application Publication
(10) Pub. No.: US 2026/0149430 A1
(43) Pub. Date: May 28, 2026

(54) Interdigital Capacitor, Acoustic Wave Device and Ladder-type Acoustic Wave Filter

(71) Applicant: Sanan Japan Technology Corporation, Tokyo (JP)

(72) Inventors: Yuki Koto, Tokyo (JP); Shinichi SHIOI, Tokyo (JP)

(21) Appl. No.: 19/401,384

(22) Filed: Nov. 26, 2025

(30) Foreign Application Priority Data
Nov. 28, 2024 (JP) 2024-207710

(51) Int. Cl. H03H 9/56; H01G 4/005; H03H 9/13

(52) U.S. Cl. CPC H03H 9/568; H01G 4/005; H03H 9/133

(57) ABSTRACT

The present invention discloses an interdigital capacitor in which excitation of elastic waves is suppressed, and an acoustic wave device including the interdigital capacitor and a resonator. The present invention provides an acoustic wave device comprising a piezoelectric substrate, a resonator formed on the piezoelectric substrate and configured to excite a wave of a main mode, and an interdigital capacitor formed on the piezoelectric substrate and comprising a pair of comb-shaped electrodes and having electrode fingers interdigitated with each other, wherein the electrode fingers of the interdigital capacitor are arranged with a non-uniform pitch so as to excite neither waves of modes other than the main mode nor a wave of the main mode.

### CROSS-REFERENCE TO RELATED APPLICATION

The present disclosure claims priority to Japanese Patent Application No. 2024-207710 filed on Nov. 28, 2024, the contents of which are herein incorporated by reference in its entirety.

### FIELD

This application relates to an interdigital capacitor formed on a piezoelectric substrate, and an acoustic wave device using a resonator formed on the piezoelectric substrate and the interdigital capacitor formed on the piezoelectric substrate.

### BACKGROUND

In an acoustic wave device using a resonator and a capacitor formed on a piezoelectric substrate, an interdigital capacitor is often used, which can reduce the number of manufacturing processes compared to a parallel-plate capacitor.

In acoustic wave devices having an acoustic wave resonator and an interdigital capacitor, as disclosed in Patent Document 1 (WO2018/051846A1) and Patent Document 2 (JP1989068114A), the extending direction of the electrode fingers of the interdigital capacitor is arranged in a direction orthogonal to the extending direction of the electrode fingers of the acoustic wave resonator. In addition, the pitch of the electrode fingers of the interdigital capacitor disclosed is uniform.

It is also known to form a resin such as polyimide on the comb-shaped electrodes of the interdigital capacitor to prevent resonance in the interdigital capacitor.

In an acoustic wave device using a resonator and an interdigital capacitor formed on a piezoelectric substrate, the reason why the direction of the electrode fingers of the resonator and the direction of the electrode fingers of the interdigital capacitor are made perpendicular is to suppress excitation of elastic waves caused by the interdigital capacitor. Resonance of the interdigital capacitor in the main mode of the resonator (for example, SH waves) can be suppressed by making the direction of the electrode fingers of the resonator perpendicular to the direction of the electrode fingers of the interdigital capacitor. However, even when resonance in the main mode is suppressed in this way, resonance of modes other than the main mode (for example, Rayleigh waves when the main mode is SH waves) still occurs. Regarding such resonance other than the main mode, it has been necessary to change the pitch of the electrode fingers of the interdigital capacitor so as to appropriately shift the resonance frequency defined by the pitch to a resonance frequency with little influence on the filter. In recent years, with carrier aggregation, filters including multiple bands have come to be incorporated into a single chip. Accordingly, the number of frequencies with little influence has been decreasing, making it increasingly difficult to select the resonance frequency of modes other than the main mode.

There has also been a problem in cases where it is difficult to add a process of forming a resin such as polyimide.

### SUMMARY

Some examples described herein may have an object to provide an acoustic wave device in which excitation of the interdigital capacitor can be suppressed.

In some examples, there is provided an interdigital capacitor formed on a piezoelectric substrate, the interdigital capacitor comprising a pair of comb-shaped electrodes having electrode fingers interdigitated with each other, wherein the interdigital capacitor has the electrode fingers arranged with a non-uniform pitch so as to excite neither waves of modes other than the main mode nor a wave of the main mode.

In some examples, the acoustic wave device of the present invention comprises:
a piezoelectric substrate;
a resonator formed on the piezoelectric substrate and configured to excite a wave of a main mode; and
an interdigital capacitor formed on the piezoelectric substrate and comprising a pair of comb-shaped electrodes having electrode fingers interdigitated with each other,
wherein the electrode fingers of the interdigital capacitor are arranged with a non-uniform pitch so as to excite neither waves of modes other than the main mode nor a wave of the main mode.

In some examples, the present invention also provides a ladder-type acoustic wave filter, comprising a plurality of series resonators, a plurality of parallel resonators, a first capacitive element, a first terminal, a second terminal, a third terminal and a ground terminal, wherein the series resonators are connected in series between the second terminal and the third terminal, and the parallel resonators are connected in parallel between the series resonators and the ground terminal, and the first capacitive element is connected in parallel to one of the series resonators thereby constituting a series resonant circuit; wherein the first capacitive element is an interdigital capacitor formed on a piezoelectric substrate, the interdigital capacitor including a pair of comb-shaped electrodes having electrode fingers interdigitated with each other, and the interdigital capacitor has the electrode fingers arranged with a non-uniform pitch so as to excite neither waves of modes other than the main mode nor a wave of the main mode.

Thus, since the interdigital capacitor has the electrode fingers arranged with a non-uniform pitch so as to excite neither waves of modes other than the main mode nor a wave of the main mode, excitation in the interdigital capacitor does not occur. Therefore, it is possible to realize an acoustic wave device that does not require adjustment of the pitch of the electrode fingers of the interdigital capacitor in order to adjust the resonance frequency of modes other than the main mode to a frequency with no influence on the filter.

As a specific embodiment of the acoustic wave device described above, the interdigital capacitor is arranged such that, in a direction orthogonal to the extending direction of the electrode fingers, the pitch of the electrode fingers gradually increases from one end of the interdigital capacitor to the other end.

As another specific embodiment of the acoustic wave device described above, the interdigital capacitor is arranged such that, in a direction orthogonal to the extending direction of the electrode fingers, the pitch of the electrode fingers from one end of the interdigital capacitor to the other end is divided into a plurality of sections in which the pitch differs between the sections, the plurality of sections being formed from a first section to an n-th section, where n is an integer of 3 or more,
wherein, within each same section among the plurality of sections, a plurality of electrode fingers are arranged with the same pitch, and
wherein, from the first section to the n-th section, the pitch of the electrode fingers gradually increases.

As another specific embodiment of the acoustic wave device described above, the pitch of the electrode fingers increases by 10% or more from the first section to the n-th section.

One embodiment of the acoustic wave device of the present invention is such that the resonator formed on the piezoelectric substrate and configured to excite a wave of a main mode includes IDT electrode fingers, and the extending direction of the IDT electrode fingers and the extending direction of the electrode fingers of the interdigital capacitor are not orthogonal.

One embodiment of the interdigital capacitor of the present invention comprises:
a piezoelectric substrate; and
an interdigital capacitor formed on the piezoelectric substrate and comprising a pair of comb-shaped electrodes having electrode fingers interdigitated with each other,
wherein the electrode fingers of the interdigital capacitor are arranged with a non-uniform pitch so as to excite neither waves of modes other than the main mode nor a wave of the main mode.

Thus, since the interdigital capacitor has electrode fingers arranged with a non-uniform pitch, excitation of waves of modes other than the main mode and excitation of a wave of the main mode do not occur. Therefore, it is possible to realize an interdigital capacitor having favorable characteristics.

As a specific embodiment of the interdigital capacitor of the present invention, the interdigital capacitor is arranged such that, in a direction orthogonal to the extending direction of the electrode fingers, the pitch of the electrode fingers gradually increases from one end of the interdigital capacitor to the other end.

According to the present invention, since excitation of waves of modes other than the main mode and excitation of a wave of the main mode do not occur in the interdigital capacitor, the characteristics of the interdigital capacitor are improved. Furthermore, in an acoustic wave device including an interdigital capacitor and a resonator, it is possible to realize an acoustic wave device in which it is unnecessary to adjust the pitch of the electrode fingers of the interdigital capacitor in order to adjust the resonance frequency of the resonator in modes other than the main mode to a frequency with no influence on the filter.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a top view illustrating a first embodiment of an acoustic wave device of the present invention.

FIG. 2 is a cross-sectional view of a resonator of the acoustic wave device according to the first embodiment of the present invention.

FIG. 3A is a schematic top view of an interdigital capacitor of the first embodiment.

FIG. 3B is a cross-sectional view along line A-A′ of the interdigital capacitor of FIG. 3A.

FIG. 4 is a top view illustrating a second embodiment of the acoustic wave device of the present invention.

FIG. 5A is a diagram showing pitch modulation of an interdigital capacitor of a conventional example.

FIG. 5B is a diagram showing the transmission characteristics of an interdigital capacitor of a conventional example.

FIG. 5C is a diagram showing Q values versus frequency of an interdigital capacitor of a conventional example.

FIG. 6A is a diagram showing pitch modulation of an interdigital capacitor of Example

1.

FIG. 6B is a diagram showing the transmission characteristics of an interdigital capacitor of Example 1.

FIG. 6C is a diagram showing Q values versus frequency of an interdigital capacitor of Example 1.

FIG. 7A is a diagram of pitch modulation of an interdigital capacitor of Example 2.

FIG. 7B is a diagram showing the transmission characteristics of an interdigital capacitor of Example 2.

FIG. 7C is a diagram showing Q values versus frequency of an interdigital capacitor of Example 2.

FIG. 8A is a diagram of pitch modulation of an interdigital capacitor of Example 3.

FIG. 8B is a diagram showing the transmission characteristics of an interdigital capacitor of Example 3.

FIG. 8C is a diagram showing Q values versus frequency of an interdigital capacitor of Example 3.

FIG. 9A is a diagram of pitch modulation of an interdigital capacitor of Comparative Example 1.

FIG. 9B is a diagram showing the transmission characteristics of an interdigital capacitor of Comparative Example 1.

FIG. 9C is a diagram showing Q values versus frequency of an interdigital capacitor of Comparative Example 1.

FIG. 10A is a diagram of pitch modulation of an interdigital capacitor of Comparative Example 2.

FIG. 10B is a diagram showing the transmission characteristics of an interdigital capacitor of Comparative Example 2.

FIG. 10C is a diagram showing Q values versus frequency of an interdigital capacitor of Comparative Example 2.

FIG. 11A is a diagram of pitch modulation of an interdigital capacitor of Comparative Example 3.

FIG. 11B is a diagram showing the transmission characteristics of an interdigital capacitor of Comparative Example 3.

FIG. 11C is a diagram showing Q values versus frequency of an interdigital capacitor of Comparative Example 3.

FIG. 12A is a diagram of pitch modulation of an interdigital capacitor of Comparative Example 4.

FIG. 12B is a diagram showing the transmission characteristics of an interdigital capacitor of Comparative Example 4.

FIG. 12C is a diagram showing Q values versus frequency of an interdigital capacitor of Comparative Example 4.

FIG. 13A is a diagram of pitch modulation of an interdigital capacitor of Comparative Example 5.

FIG. 13B is a diagram showing the transmission characteristics of an interdigital capacitor of Comparative Example 5.

FIG. 13C is a diagram showing Q values versus frequency of an interdigital capacitor of Comparative Example 5.

FIG. 14 is a diagram showing a circuit configuration of a ladder-type acoustic wave filter 1 to which an embodiment of the present invention is applied.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

In order to make the objectives, features, and advantages of the present invention more clearly understood, specific embodiments of the invention are described in detail below with reference to the accompanying drawings.

To facilitate a better understanding of the technical solutions of the invention for those skilled in the art, the following descriptions of the embodiments of the invention are provided clearly and comprehensively with reference to the accompanying drawings. It should be understood that the described embodiments are only part of the invention and not exhaustive. All other embodiments obtained by those skilled in the art without involving inventive activity, based on the disclosed embodiments, shall fall within the scope of protection of the invention.

It should also be noted that the terms “first,” “second,” and so on, used in the specification, claims, and drawings of the invention, are merely to distinguish similar elements and do not imply a particular sequence or order. These terms can be used interchangeably when appropriate, so that the embodiments of the invention can be implemented in sequences other than those illustrated or described. Furthermore, the terms “include”, “comprise” and variations thereof are intended to be non-exclusive. For example, a process, method, system, product, or apparatus that comprises a series of steps or elements is not limited to only those explicitly listed but may also include other steps or elements that are inherent or not expressly stated.

Additionally, it should be noted that the division of embodiments in this disclosure is made for ease of explanation and should not be interpreted as limiting. Features of the various embodiments may be combined or referenced where there is no conflict.

### First Embodiment

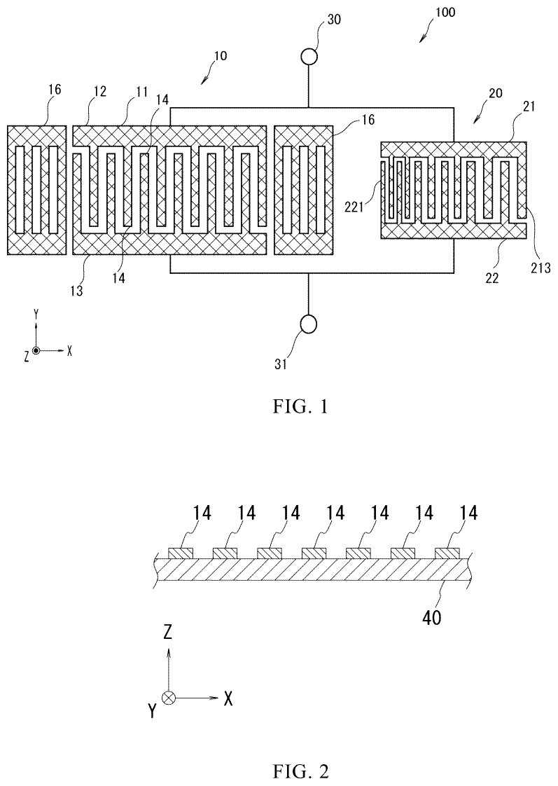

FIG. 1 is a diagram showing a first embodiment of an acoustic wave device. A resonant circuit 100 as the acoustic wave device includes a resonator 10, an interdigital capacitor 20, terminals 30 and terminals 31. The resonator (SAW resonator) 10 and the interdigital capacitor 20 are connected in parallel.

The resonator 10 includes an IDT electrode 11 and a reflector 16. The IDT electrode 11 includes opposing comb-shaped electrodes 12 and 13, and the comb-shaped electrodes 12 and 13 include electrode fingers 14.

FIG. 2 is a cross-sectional view of the resonator 10. Electrode fingers 14 are provided on a piezoelectric substrate 40.

As the piezoelectric substrate 40, for example, lithium tantalate (LiTaO₃) is used. However, the material of the piezoelectric substrate 40 is not limited thereto, and another material such as lithium niobate (LiNbO₃) may be used.

It is necessary that at least the piezoelectric substrate 40 be provided. A support substrate (not shown) may be provided under the piezoelectric substrate 40. An intermediate layer may be provided under the piezoelectric substrate 40, and a support substrate may be provided under the intermediate layer.

As the support substrate, for example, a spinel substrate may be used, but another material may also be used, such as a sapphire substrate, a silicon substrate, a quartz substrate, a silica substrate, an alumina substrate, or a silicon carbide substrate.

As for the intermediate layer, for example, when it is provided for the purpose of improving the temperature characteristics of the acoustic wave device, silicon dioxide (SiO₂) or the like is used as the intermediate layer. When the intermediate layer is provided as a layer for increasing the propagation velocity of the acoustic wave, aluminum nitride (AlN) or boron-aluminum nitride (BₓAl₁₋ₓN), for example, is used.

As shown in FIG. 1, the interdigital capacitor 20 includes a first comb-shaped electrode 21 and a second comb-shaped electrode 22.

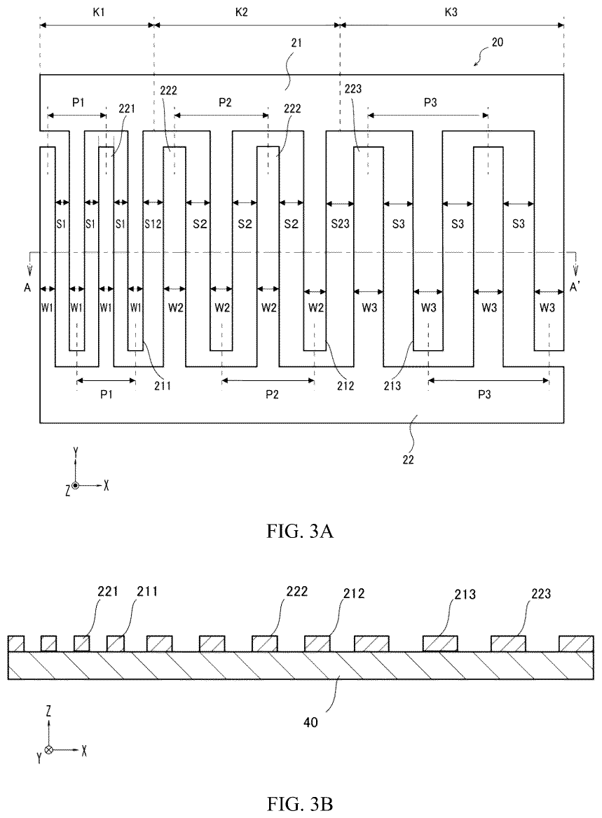

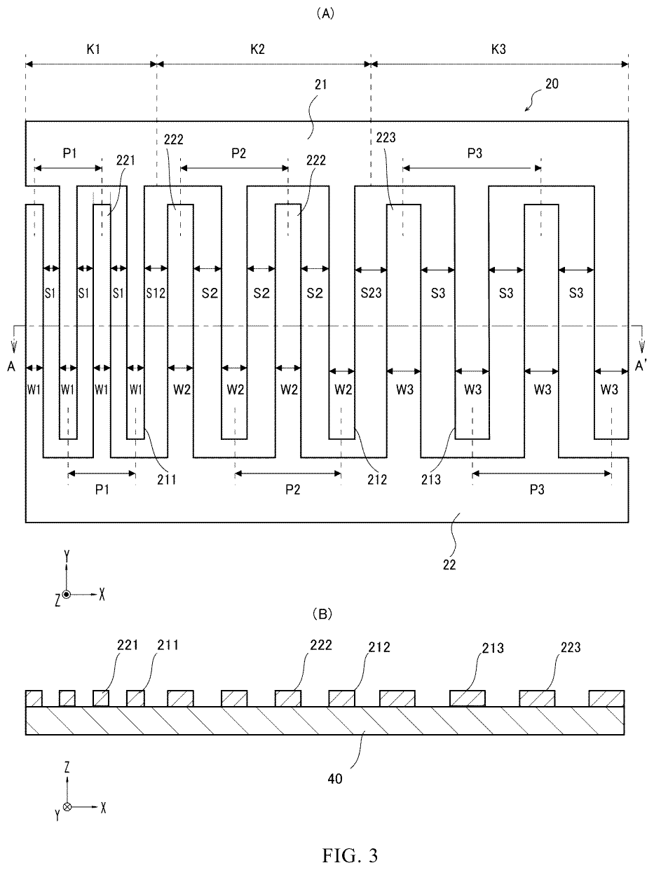

FIG. 3A is a schematic top view of the interdigital capacitor 20. FIG. 3B is an A-A′ cross-sectional view of the interdigital capacitor 20.

As shown in FIG. 3A, the interdigital capacitor 20 includes a pair of the comb-shaped electrode 21 and the comb-shaped electrode 22. The comb-shaped electrode 21 includes electrode fingers 211, 212, and 213. The comb-shaped electrode 22 includes electrode fingers 221, 222, and 223. The electrode fingers 211, 212, and 213 of the comb-shaped electrode 21 and the electrode fingers 221, 222, and 223 of the comb-shaped electrode 22 are interdigitated with each other.

The interdigital capacitor 20 has a first section K1, a second section K2, and a third section K3.

The first section K1 is a section in which electrode fingers are arranged at an equal pitch P1, the widths of the electrode fingers 211 and 221 are W1, and the distance between the electrode finger 211 and the electrode finger 221 is S1.

The second section K2 is a section in which electrode fingers are arranged at an equal pitch P2, the widths of the electrode fingers 212 and 222 are W2, and the distance between the electrode finger 212 and the electrode finger 222 is S2.

The third section K3 is a section having a pitch P3, the widths of the electrode fingers 213 and 223 are W3, and the distance between the electrode finger 213 and the electrode finger 223 is S3.

As described above, in the interdigital capacitor 20, in a direction orthogonal to the extending direction of the electrode fingers such as the electrode finger 213 (the X direction in FIG. 3A), the three sections, namely the first section K1, the second section K2, and the third section K3, are provided. The pitches P1, P2, and P3 for the respective sections are the same within the same section, but, on FIG. 3A, as proceeding in the X direction, P1, P2, and P3 gradually increase. Therefore, since the pitch of the electrode fingers is arranged non-uniformly, excitation of waves of modes other than the main mode and excitation of a wave of the main mode in the interdigital capacitor 20 can be suppressed. As a result, it is possible to realize the interdigital capacitor 20 with few resonances and good characteristics.

Further, because excitation of waves of modes other than the main mode and excitation of a wave of the main mode can be suppressed, whereas in conventional acoustic wave devices it is necessary to make the electrode fingers 14 of the resonator 10 and the electrode fingers 211 and the like of the interdigital capacitor 20 orthogonal to suppress resonance, in the present embodiment such necessity does not exist. Therefore, as shown in FIG. 1, the electrode fingers 14 of the IDT electrode 11 of the resonator 10 and the electrode fingers 211 of the interdigital capacitor 20 need not be orthogonal. Consequently, unlike in the conventional case, there is no limitation on the arrangement direction of the interdigital capacitor 20, providing the advantage of increased design flexibility in layout. Note that, as shown in FIG. 1, the electrode fingers 211 and the like of the interdigital capacitor 20 are parallel, as one example of a non-orthogonal angle, to the electrode fingers 14 of the IDT electrode 11 of the resonator 10; however, the two need not necessarily be parallel, and, for example, they may be arranged at an inclination.

In the present embodiment, the distance S12 between the electrode finger 211 of the first section K1 and the electrode finger 212 of the second section K2 is the average of the distances S1 and S2; however, the distance S12 may be made the same as the shorter adjacent distance S1, or may be made the same as the longer adjacent distance S2.

Similarly, in the present embodiment, the distance S23 between the electrode finger 212 of the second section K2 and the electrode finger 223 of the third section K3 is the average of the distances S2 and S3; however, the distance S23 may be made the same as the shorter adjacent distance S2, or may be made the same as the longer adjacent distance S3.

As shown in FIG. 3B, the electrode fingers 211, 212, 213, 221, 222, and 223 are provided on the piezoelectric substrate 40. As stated above, a support substrate or an intermediate layer may be provided under the piezoelectric substrate 40.

### Second Embodiment

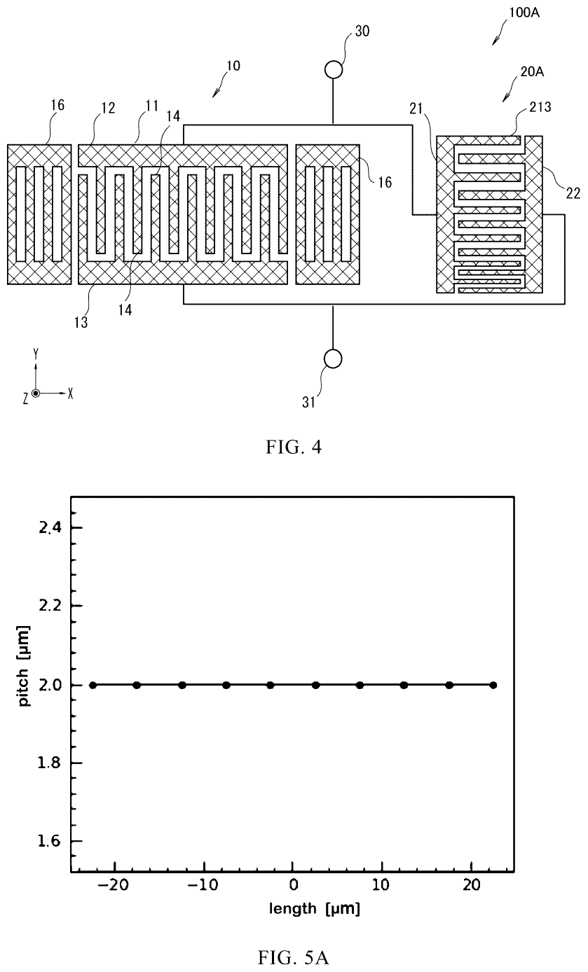

FIG. 4 is a diagram showing a second embodiment of the acoustic wave device. A resonant circuit 20A as the acoustic wave device includes a resonator 10 and an interdigital capacitor 20A. Portions having the same roles and names as in the first embodiment are denoted by the same reference numerals, and description thereof is omitted.

In the second embodiment, the orientation of the electrode fingers 213 of the interdigital capacitor 20A is orthogonal to the electrode fingers 14 of the resonator 10. The acoustic wave device of the present invention can also be applied to such an embodiment.

### <Regarding Simulation>

To confirm the effects of Embodiments 1 and 2 described above, simulations were conducted. Items common to the examples and comparative examples in the simulations are as follows:

Piezoelectric substrate material: lithium tantalate of 42° Y-rotated, X-propagation (no intermediate layer or support substrate was provided).
Aperture length: 22.0 μm
Number of finger pairs: 45
Base pitch (median of pitch): 2.0 μm
Duty: 50%
No reflector
Material of the electrode fingers of the interdigital capacitor: an aluminum-based alloy

TABLE 1

| | section | Overall Pitch P | Finger | Per-Section Pitch P | Variation Mode of | |
|---|---|---|---|---|---|---|
| Example | count | Increase Rate | Pairs/Section | Increase Rate | Pitch P | Evaluation |
| Example 1 | 9 | ±20% | 5 | 5.00% | Monotonic increase | A |
| Example 2 | 9 | ±10% | 5 | 2.50% | Monotonic increase | B |
| Example 3 | 5 | ±10% | 9 | 5.00% | Monotonic increase | B |
| Comparative | 3 | ±20% | 15 | 20.00% | Monotonic increase | C |
| Example 1 | | | | | | |
| Comparative | 3 | ±10% | 15 | 10.00% | Monotonic increase | C |
| Example 2 | | | | | | |
| Comparative | 9 | ±5% | 5 | 1.25% | Monotonic increase | C |
| Example 3 | | | | | | |
| Comparative | 9 | ±10% | 5 | Random | Increase/Decrease | C |
| Example 4 | | | | | Present (the | |
| | | | | | intermediate sections | |
| | | | | | are random) | |
| Comparative | 9 | ±20% | 5 | In principle 5.00% | Increase/Decrease | C |
| Example 5 | | | | | Present | |
| | | | | | (Swap seventh and | |
| | | | | | eighth sections of | |
| | | | | | Example 2) | |
| Conventional | 1 | 0% | 45 | 0.00% | — | D |
| Example | | | | | | |

Table 1 provides a list summarizing the outlines and evaluations of the examples and comparative examples described later.

The evaluations in Table 1 were made on four levels: A, B, C, and D. “D” indicates that the effect of suppressing excitation is substantially the same as that in the conventional example, “A” indicates an excellent effect of suppressing excitation, “B” indicates that an effect of suppressing excitation is obtained, but it is inferior to “A.” and “C” indicates that the effect of suppressing excitation has shown some degree of improvement, but it is inferior to “B”. The “overall pitch P increase rate” and the “per-section pitch P increase rate” will be described later in the explanation of Example 1.

From these results, the following tendencies were found. (1) In the direction orthogonal to the electrode fingers (the X direction in FIG. 3), when the pitch is increased monotonically (meaning it does not decrease and only increases), excitation tends to be more easily suppressed. That is, in the direction orthogonal to the electrode fingers, when the pitch repeatedly increases and decreases, the effect of suppressing excitation tends to be weakened. (2) A larger number of sections makes excitation easier to suppress. (3) A higher pitch increase rate makes excitation easier to suppress. The following will describe this using the diagrams of the simulation results.

### Conventional Example

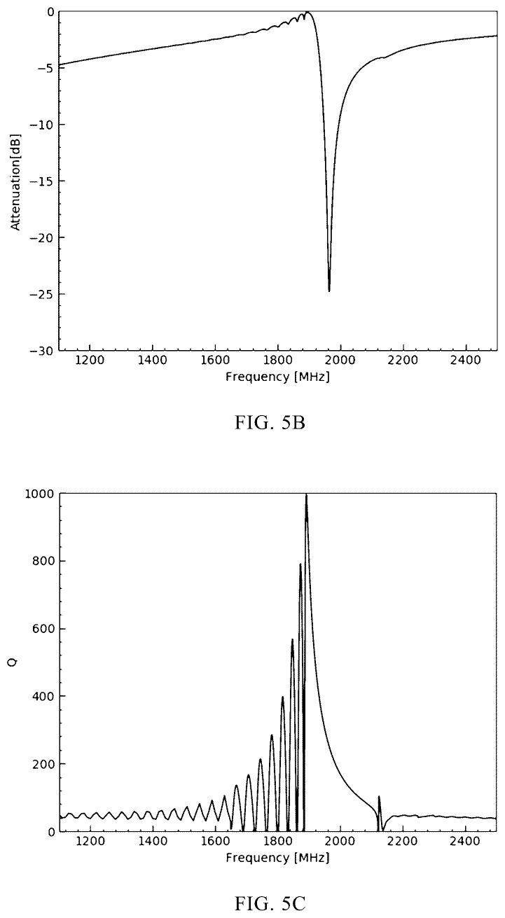

FIG. 5A is a diagram of pitch modulation of an interdigital capacitor in a conventional example. In the pitch modulation diagram, the horizontal axis indicates a distance (Length) [μm] in a direction orthogonal to the extending direction of the electrode fingers, where the center is set to zero and the rightward direction is the positive direction (corresponding to the X direction in FIG. 3). The vertical axis is the pitch P [μm] of the electrode fingers.

In this conventional example, the pitch P of the electrode fingers of the interdigital capacitor is uniform and is 2.0 [μm]. FIG. 5B shows attenuation versus frequency as the transmission characteristics [dB] of this conventional example. According to FIG. 5B, the attenuation becomes large near 1960 [MHz], and it can be seen that this frequency is the antiresonant frequency of the interdigital capacitor. This antiresonant frequency is considered to be caused by excitation of elastic waves by the interdigital capacitor.

FIG. 5C shows the Q value versus frequency in this conventional example. In this conventional example, due to excitation, there are frequencies at which the Q value is high, for example 300 or higher. Therefore, in the conventional example, when used as a capacitor, there is a problem that the excited elastic waves resonate and cause loss. When used as a capacitor, it is desirable for the Q value to be lower so that the loss becomes smaller. In view of this, simulations were performed for Examples 1 to 3 and Comparative Examples 1 to 5 below.

### Example 1

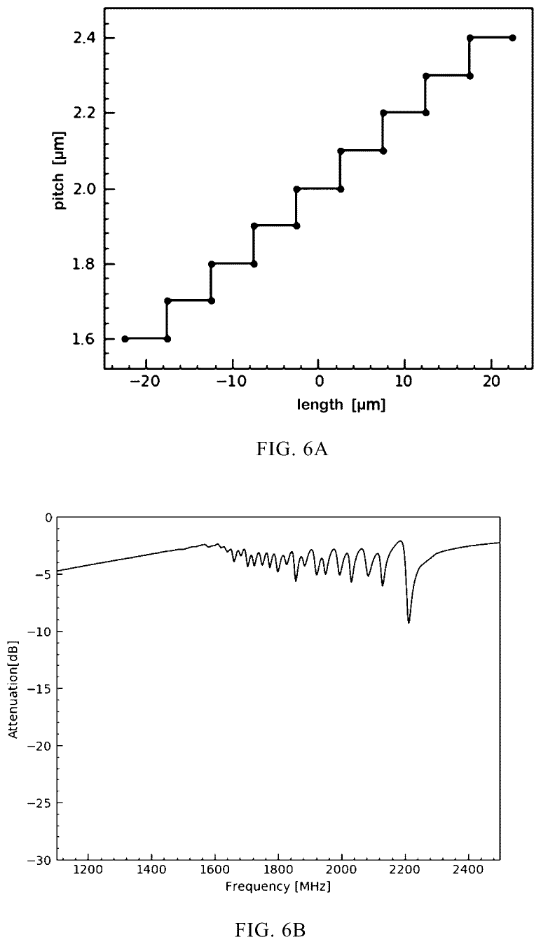

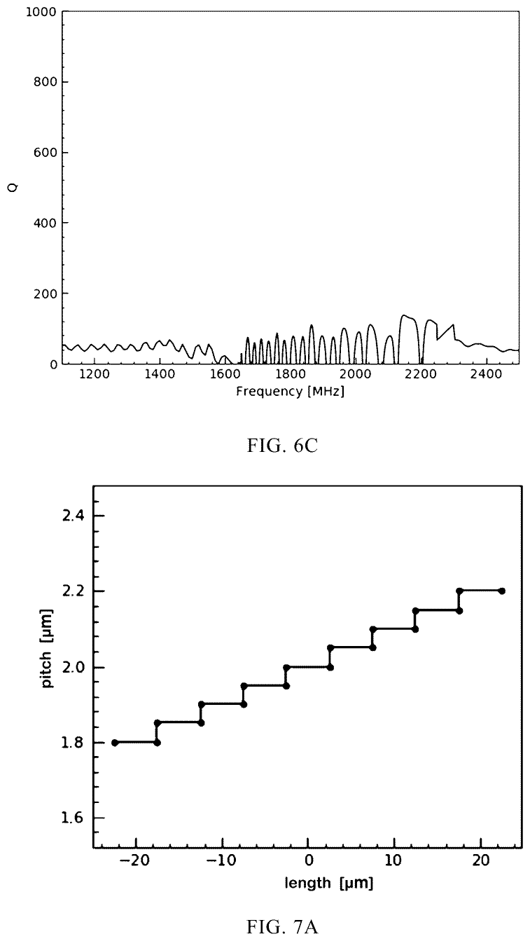

The interdigital capacitor of Example 1 in FIG. 6A will be described to show that excitation is suppressed. FIG. 6A is a diagram of pitch modulation of the interdigital capacitor of Example 1. In Example 1, the interdigital capacitor is divided into nine sections having different electrode finger pitches P, regarding a portion of common electrode finger pitch P as one section. In FIG. 6A, the leftmost section having a common pitch P is referred to as the first section, and the sections each having a common pitch P and adjacent rightward to the first section are referred to, in order from the left, as the second section, third section, and so on, and the rightmost section is referred to as the ninth section. In FIG. 6A, regarding the horizontal axis for the distance (Length), the left end is around −22 [μm], the right end is around 22 [μm], and the center is the distance 0 [μm]. The vertical axis is the pitch P [μm] of the electrode fingers.

The overall pitch P increase rate is ±20%. The “overall pitch P increase rate” will be explained. The “overall pitch P increase rate” is the rate of change of the pitch P of the left-end section and the right-end section relative to the central pitch P. Specifically, as shown in FIG. 6A, the overall pitch P increase rate represents the increase rates of the pitch P of the leftmost first section (around the distance −22 [μm]), which has a shorter distance, and of the rightmost ninth section (around the distance 22 [μm]), which has the longest distance, taking the pitch 2.0 [μm] at the distance zero on the horizontal axis as 0%. In Example 1, the pitch P at distance 0 is 2.0 [μm]. In the leftmost first section, since the pitch P is 1.6 [μm], it is −20% relative to the pitch P at distance 0, and in the rightmost ninth section, since the pitch P is 2.4 [μm], the pitch P is +20%. The manner of pitch increase in such pitch modulation is referred to as an “overall pitch P increase rate of ±20%.”

The “per-section pitch P increase rate” will be specifically explained. The “per-section pitch P increase rate” is the rate of change of the pitch between adjacent sections. As shown in FIG. 6A, from the first section (pitch) around a distance (Length) of −20 [μm] on the horizontal axis, in the direction in which the distance increases, moving to the second section, third section, and fourth section, i.e., to each section adjacent to the previous one, the pitch P increases by 5.00% per section. This manner of pitch increase per section is referred to as a “per-section pitch P increase rate of 5.00%.” Note that this “per-section pitch P increase rate of 5.00%,” like the “overall pitch P increase rate of ±20%,” is based on the pitch P at the position of distance 0. The meanings of “overall pitch P increase rate” and “per-section pitch P increase rate” are the same in the other examples and comparative examples.

FIG. 6B shows attenuation versus frequency as the transmission characteristics [dB] of Example 1. In FIG. 6B, Example 1 shows a tendency for the attenuation peak to be smaller than in the conventional example.

FIG. 6C shows the Q value versus frequency of Example 1. The Q value of Example 1 does not exceed 200 and can be said to be significantly lower than the Q value of the conventional example (FIG. 5C). Therefore, in the interdigital capacitor, excitation is suppressed, and it is seen that there is an effect of suppressing loss due to resonance. In Table 1, the evaluation of Example 1 was rated as A.

### Example 2

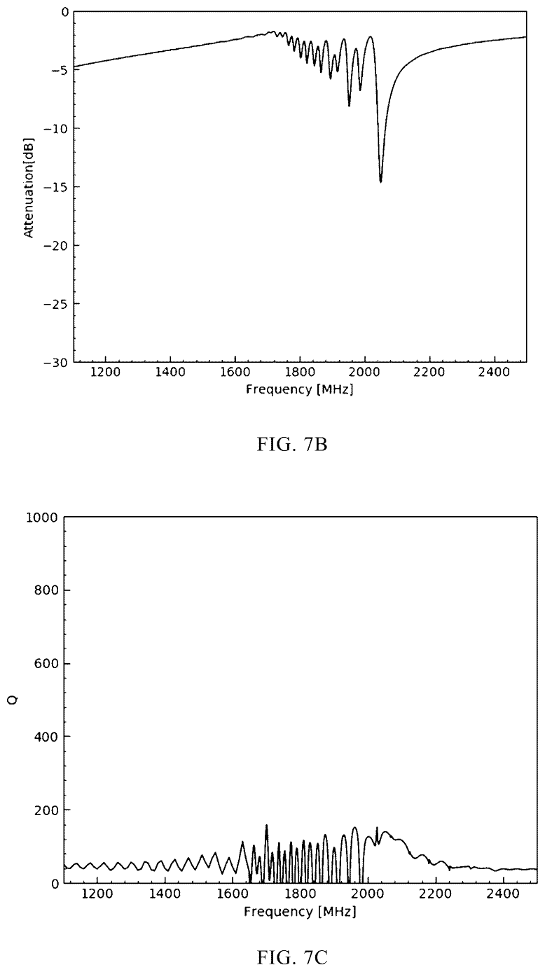

The interdigital capacitor of Example 2 in FIG. 7A will be described to show that excitation is suppressed. FIG. 7A is a diagram of pitch modulation of the interdigital capacitor of Example 2. In Example 2, the interdigital capacitor is divided into nine sections having different electrode finger pitches P. Since the sections divided into nine increase by 2.5% as the distance (Length) increases, the per-section pitch P increase rate is 2.5%. The pitch P at distance 0 is 2.0 [μm], and in the leftmost section the pitch P is 1.8 [μm], i.e., −10%, while in the rightmost section the pitch P is 2.2 [μm], i.e., +10%. The “overall pitch P increase rate” is ±10%. FIG. 7B shows the transmission characteristics [dB] of this Example 2. In FIG. 7B, Example 2 shows a tendency for the attenuation peak to be smaller than in the conventional example. FIG. 7C shows the Q value versus frequency of this Example 2. The Q value of Example 2 does not exceed 200 and can be said to be significantly lower than the Q value of the conventional example (FIG. 5C). Therefore, in the interdigital capacitor, excitation is suppressed, and it is seen that there is an effect of suppressing loss due to resonance.

However, the Q value of Example 2 (FIG. 7C) tends to be higher than the Q value of Example 1 (FIG. 6C). Therefore, Example 2 is considered to have a weaker effect of suppressing excitation than Example 1. Accordingly, in Table 1, the evaluation of Example 2 was rated as B.

### Example 3

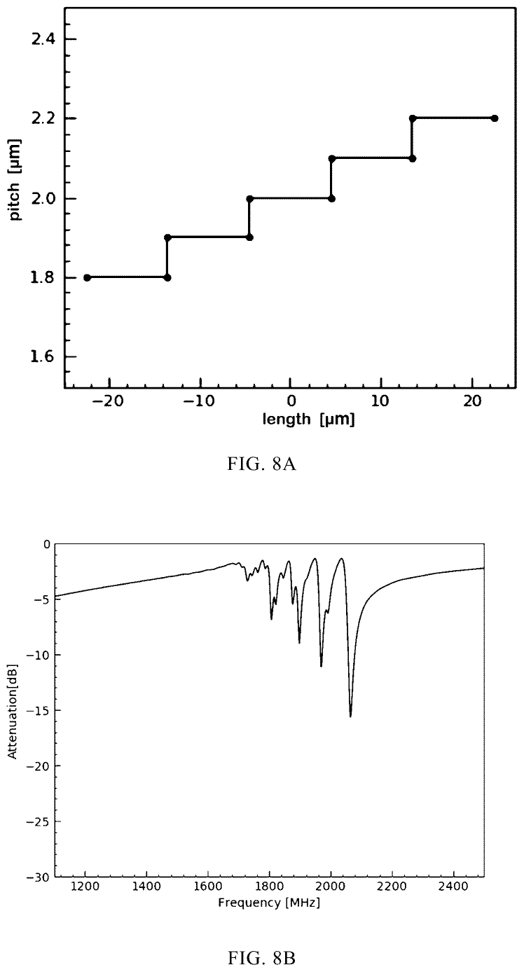

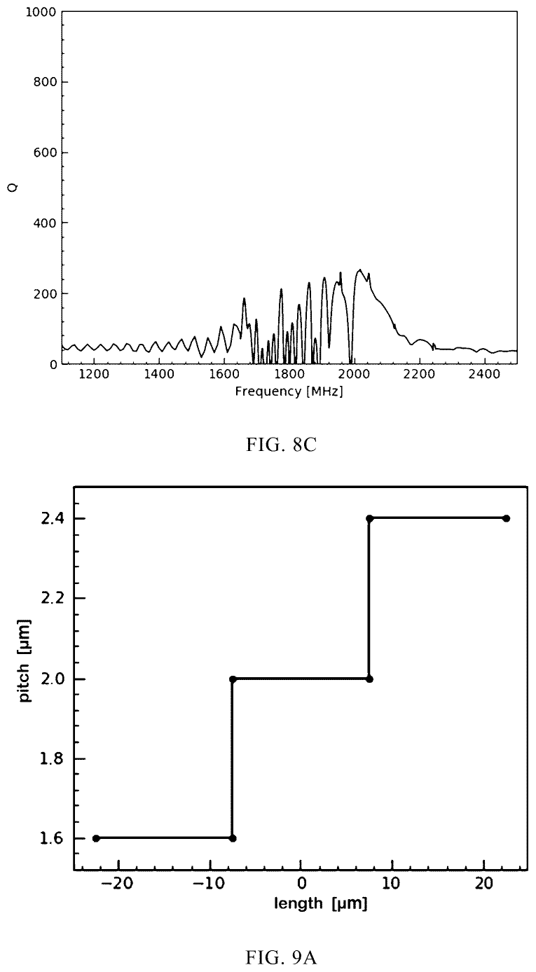

The interdigital capacitor in FIG. 8A will be described to show that excitation is suppressed. FIG. 8A is a diagram of pitch modulation of the interdigital capacitor of Example 3. In Example 3, the interdigital capacitor is divided into five sections having different electrode finger pitches P. Since the sections divided into five increase by 5% as the distance (Length) increases, the per-section pitch P increase rate is 5%. The pitch P at distance 0 is 2.0 [μm], and in the leftmost section the pitch P is 1.8 [μm], i.e., −10%, while in the rightmost section the pitch P is 2.2 [μm], i.e., +10%. The “overall pitch P increase rate” is ±10%.

FIG. 8B shows the transmission characteristics [dB] of this Example 3. In FIG. 8B, Example 3 shows a tendency for the attenuation peak to be smaller than in the conventional example.

FIG. 8C shows the Q value versus frequency of this Example 3. The Q value of Example 3 does not exceed 300 and can be said to be significantly lower than the Q value of the conventional example (FIG. 5C). Therefore, in the interdigital capacitor, excitation is suppressed, and it is seen that there is an effect of suppressing loss due to resonance.

However, the Q value of Example 3 (FIG. 8C) tends to be higher than the Q value of Example 2 (FIG. 7C). Therefore, Example 3 is considered to have a weaker effect of suppressing excitation than Example 2. From this, in cases where the pitch only increases with distance (monotonically increases and does not decrease in the middle), it is considered that the greater the number of sections, the higher the effect of suppressing excitation. In Table 1, the evaluation of Example 3 was rated as B.

### Comparative Example 1

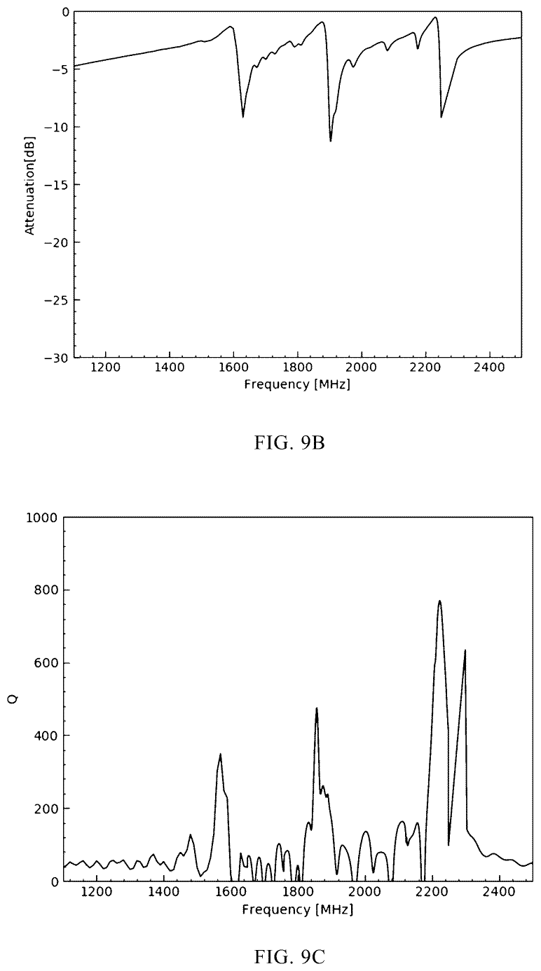

It was found that in the interdigital capacitor of Comparative Example 1 of FIG. 9A, the effect of suppressing excitation is weak. Further, by comparison between Comparative Example 1 and Example 3, in cases where the pitch only increases with distance (monotonically increases and does not decrease), it is considered that the greater the number of sections, the higher the effect of suppressing excitation. This will be explained below.

In Comparative Example 1, the interdigital capacitor is divided into three sections having different electrode finger pitches P. Since the sections divided into three increase by 20% as the distance (Length) increases, the per-section pitch P increase rate is 20%. The pitch P at distance 0 is 2.0 [μm], and in the leftmost section the pitch P is 1.6 [μm], i.e., −20%, while in the rightmost section the pitch P is 2.4 [μm], i.e., +20%. The “overall pitch P increase rate” is ±20%.

FIG. 9B shows the transmission characteristics [dB] of this Comparative Example 1. In FIG. 9B, Comparative Example 1 shows a tendency for the attenuation peak to be smaller than in the conventional example.

FIG. 9C shows the Q value versus frequency of this Comparative Example 1. Compared with the Q value of the conventional example (FIG. 5C), it is lower, and excitation is suppressed to some extent. However, in Comparative Example 1 there are frequencies at which the Q value exceeds 300. As such, Comparative Example 1 has a low effect of suppressing excitation. Therefore, in Table 1, the evaluation of Comparative Example 1 was rated as C.

The Q value peak (FIG. 9C) of Comparative Example 1 tends to be higher than the Q value peak (FIG. 8C) of Example 3. Therefore, it is considered that Comparative Example 1 has a lower effect of suppressing excitation than Example 3. From this, in cases where the pitch only increases with distance (monotonically increases and does not decrease), it is considered that the greater the number of sections, the higher the effect of suppressing excitation.

### Comparative Example 2

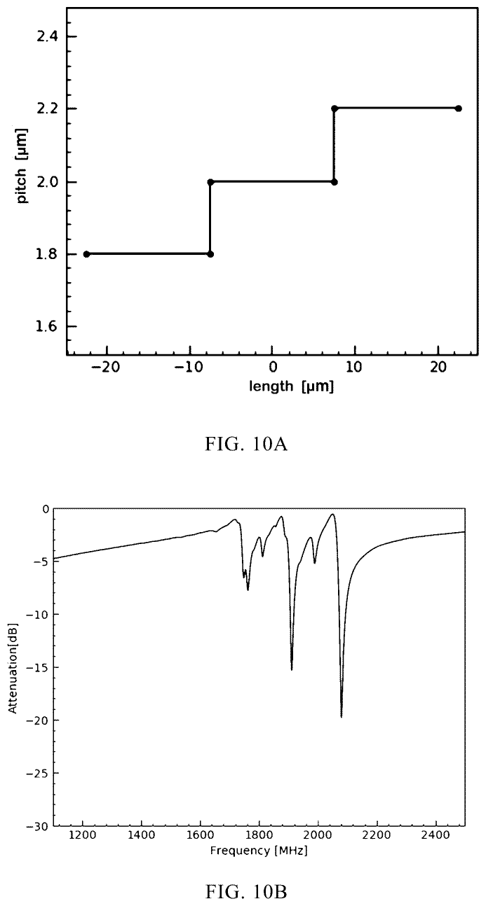

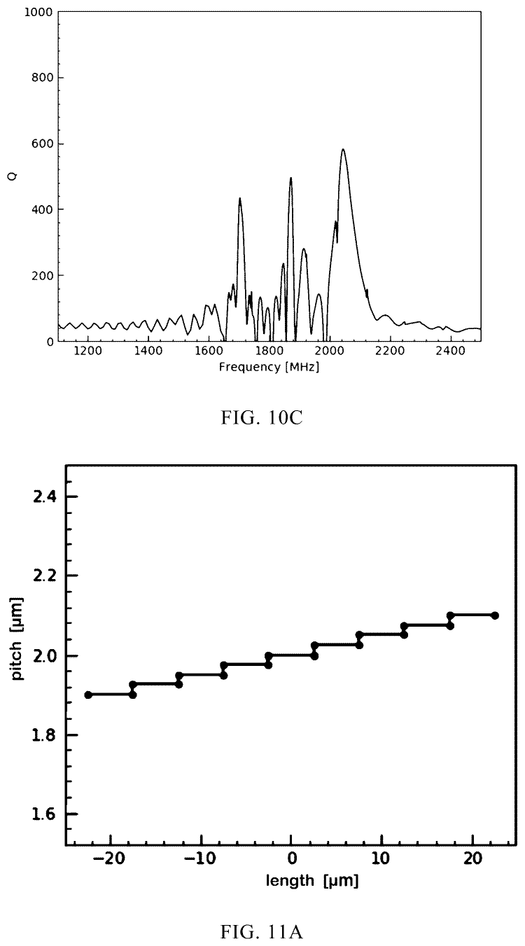

It was found that in the interdigital capacitor of Comparative Example 2 of FIG. 10A, the effect of suppressing excitation is lower than in Example 3.

FIG. 10A is a diagram of pitch modulation of the interdigital capacitor of Comparative Example 2. In Comparative Example 2, since the sections divided into three increase by 10% as the distance (Length) increases, the per-section pitch P increase rate is 10%. The pitch P at distance 0 is 2.0 [μm], and in the leftmost section the pitch P is 1.8 [μm], i.e., −10%, while in the rightmost section the pitch P is 2.2 [μm], i.e., +10%. The “overall pitch P increase rate” is ±10%.

FIG. 10B shows the transmission characteristics [dB] of this Comparative Example 2. In FIG. 10B, Comparative Example 2 shows a tendency for the attenuation peak to be smaller than in the conventional example. However, in Comparative Example 2 the peak of insertion loss is larger than in Example 3.

FIG. 10C shows the Q value versus frequency of this Comparative Example 2. The Q value of Comparative Example 2 is lower than the Q value of the conventional example (FIG. 5C), and an effect of suppressing excitation is observed to some extent. The Q value of Comparative Example 2 exceeds 300. Therefore, it can be said that in the interdigital capacitor of Comparative Example 2, the effect of suppressing excitation is low. From these facts, in Table 1, the evaluation of Comparative Example 2 was rated as C, which is lower than Example 3.

### Comparative Example 3

It was found that the interdigital capacitor of Comparative Example 3 has a lower effect of suppressing excitation than Example 2.

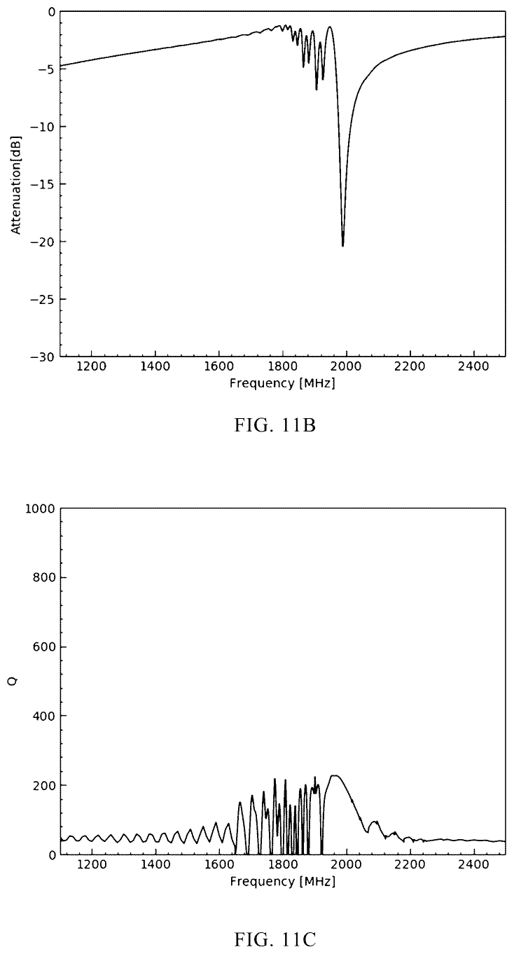

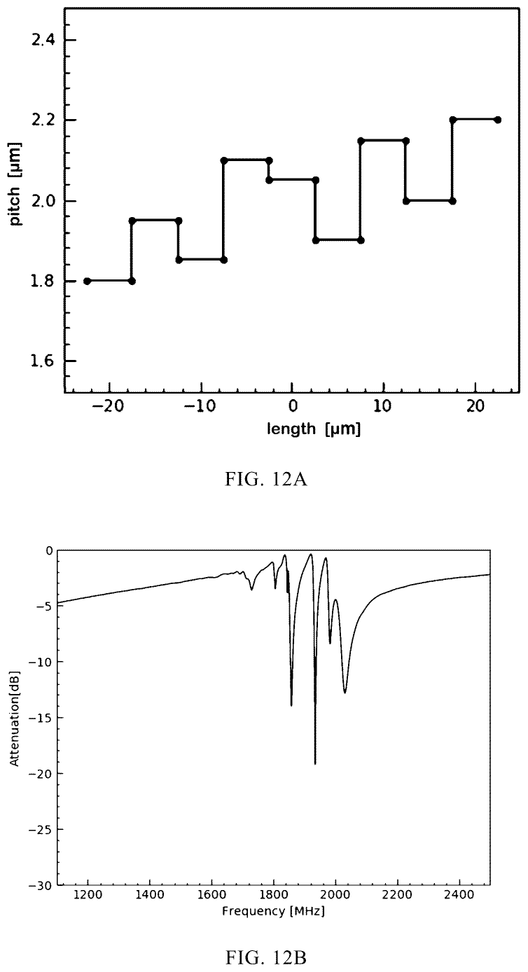

FIG. 11A is a diagram of pitch modulation of the interdigital capacitor of Comparative Example 3. In Comparative Example 3, since the sections divided into nine increase by 1.25% as the distance (Length) increases, the per-section pitch P increase rate is 1.25%. The pitch P at distance 0 is 2.0 [μm], and in the leftmost section the pitch P is 1.9 [μm], i.e., −5%, while in the rightmost section the pitch P is 2.1 [μm], i.e., +5%. The “overall pitch P increase rate” is ±5%.

FIG. 11B shows the transmission characteristics [dB] of this Comparative Example 3. In FIG. 11B, Comparative Example 3 shows a tendency for the attenuation peak to be smaller than in the conventional example. However, in Comparative Example 3, the peak of insertion loss is larger than in Example 2 (FIG. 7B).

FIG. 11C shows the Q value versus frequency of this Comparative Example 3. The Q value of Comparative Example 3 is lower than the Q value of the conventional example (FIG. 5C), and an effect of suppressing excitation is observed to some extent.

From these facts, in Table 1, the evaluation of Comparative Example 3 was rated low as C.

By comparison between this Comparative Example 3 (nine sections and an increase rate of 5%) and Example 2 (nine sections and an increase rate of 10%), it was found that the higher the per-section pitch P increase rate, the higher the effect of suppressing excitation. Further, by comparison between Comparative Example 3 and Example 2, it can be said that the per-section pitch P increase rate is preferably 10% or more.

### Comparative Example 4

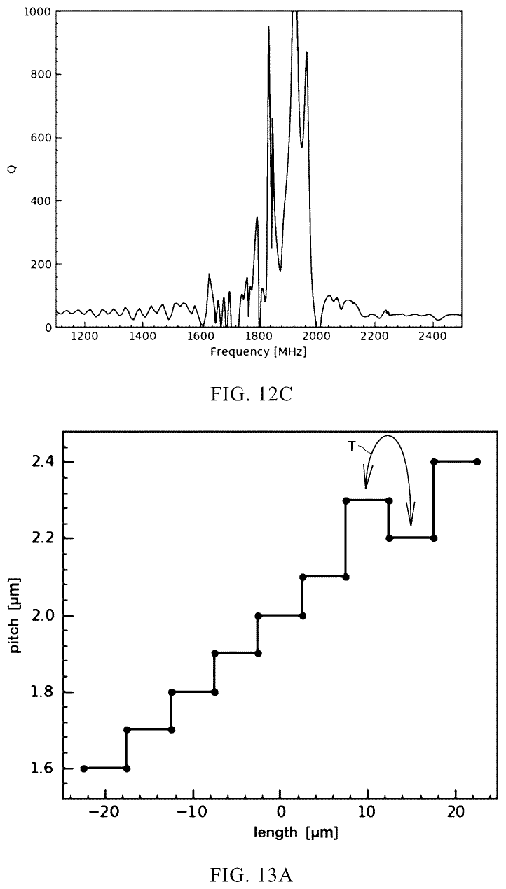

In the interdigital capacitor of Comparative Example 4 shown in FIG. 12A, it was found, as described below, that the effect of suppressing excitation is lower than in Examples 1 to 3. FIG. 12A is a diagram of pitch modulation of the interdigital capacitor of Comparative Example 4. In Comparative Example 4, the interdigital capacitor is divided into nine sections having different electrode finger pitches P. In the first section at the left end of the horizontal axis, i.e., around −22 [μm] in distance (Length), the pitch P is 1.8 [μm], and in the ninth section at the right end, i.e., around +22 [μm], the pitch P is 2.2 [μm]; therefore, the overall pitch P increase rate is ±10%. The overall pitch P increase rate of Comparative Example 4 is the same as the overall pitch P increase rate of Example 2. The pitches P of the intermediate sections other than the first section at the left end and the ninth section at the right end (the second to eighth sections from the left) were randomly varied.

FIG. 12B shows the transmission characteristics [dB] of this Comparative Example 4. In FIG. 12B, Comparative Example 4 shows a tendency for the attenuation peak to be smaller than in the conventional example. However, in Comparative Example 4 the peak of insertion loss is larger than in Example 2 (FIG. 7B).

FIG. 12C shows the Q value versus frequency of this Comparative Example 4. In Comparative Example 4, a large peak exceeding 600 appears, and a tendency is observed for the Q value to be higher than the Q value of Example 2 (FIG. 7C). From these facts, in Table 1, the evaluation of Comparative Example 4 was rated low as C.

By comparison between this Comparative Example 4 (nine sections, an overall pitch P increase rate of ±10% at both ends, and randomly varied pitches in the intermediate sections other than the ends) and Example 2 (nine sections, an overall pitch P increase rate of ±10%, and a case in which the pitch P simply increases by 2.5% from left to right), it was found that a configuration in which the pitch in the sections increases with increasing distance exhibits a higher effect of suppressing excitation, whereas a configuration in which the pitch does not simply increase with increasing distance and decreases partway exhibits a lower effect of suppressing excitation.

### Comparative Example 5

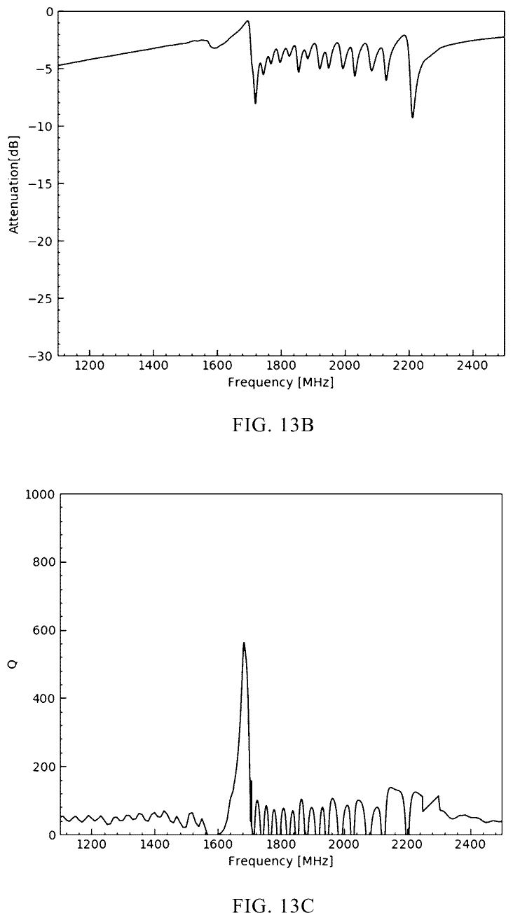

In the interdigital capacitor of Comparative Example 5 shown in FIG. 13A, it was found, as described below, that the effect of suppressing excitation is lower than in Example 1. FIG. 13A is a diagram of pitch modulation of the interdigital capacitor of Comparative Example 5. In Comparative Example 5, as in Example 1, the interdigital capacitor pitch is divided into nine sections. In Comparative Example 5, the pitch P at distance 0 is 2.0 [μm]; in the leftmost section the pitch P is 1.6 [μm], i.e., −20%, and in the rightmost section the pitch P is 2.4 [μm], i.e., +20%; therefore, the “overall pitch P increase rate” is ±20%. The per-section pitch P increase rate is 5% from the first section at the left end to the sixth section. Although, in principle, the per-section pitch P increase rate is 5%, as indicated by arrow T in FIG. 13A, what differs from the interdigital capacitor of Example 1 (FIG. 6A) is that the pitches of the seventh and eighth sections counted from the left are swapped.

FIG. 13B shows the transmission characteristics [dB] of this Comparative Example 5. In FIG. 13B, Comparative Example 5 shows a tendency for the attenuation peak to be smaller than in the conventional example.

FIG. 13C shows the Q value versus frequency of this Comparative Example 5. In Comparative Example 5, a large peak appears, and a tendency is observed for the values to be higher than the Q values of Example 1 (FIG. 6C) and Example 2 (FIG. 7C). From these facts, Comparative Example 5 is considered to have a low effect of suppressing excitation. Accordingly, in Table 1, the evaluation of Comparative Example 5 was rated low as C.

By comparison between this Comparative Example 5 (as shown in FIG. 13A, nine sections, the overall pitch P increase rate is ±20%, the per-section pitch P increase rate is, in principle, 5%, but the pitches of the seventh and eighth sections from the left in the pitch modulation of Example 1 are swapped) and Example 1 (the total number of sections is nine, the overall pitch P increase rate is ±20%, and the per-section pitch P increase rate is 5%), it was found that a configuration in which the pitch P of the sections simply increases (does not decrease partway) with increasing distance has a higher effect of suppressing excitation, whereas a configuration in which the pitch P decreases even at a single location as the distance increases has a lower effect of suppressing excitation.

As a result of the above simulations, Table 1 became as described above, and the conclusions (1) to (3) mentioned above were reached.

Furthermore, from these simulations, in implementing the present invention, since the effect of suppressing excitation increases with a larger number of sections, the number of sections may be nine or more, the number of finger pairs in one section may be reduced, and the pitch may be gradually increased with distance. The conditions such as duty and the number of finger pairs may also be changed. Moreover, in Examples 1 to 3 above, the left and right may be reversed so that the pitch decreases from the leftmost section to the rightmost section.

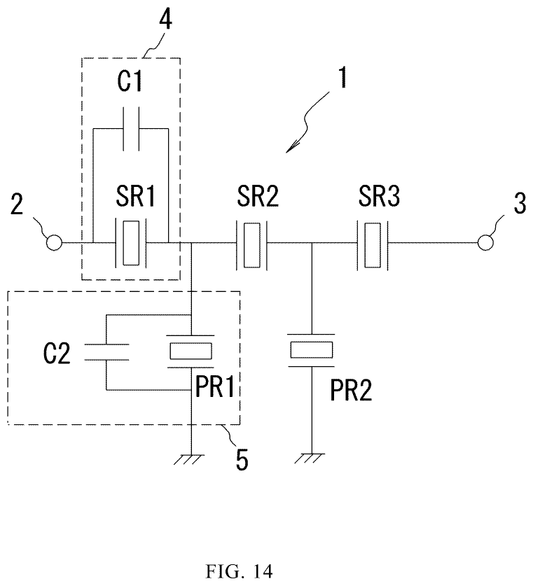

The resonant circuits 100 and 100A, which are acoustic wave devices according to the present invention, can be applied to a ladder-type acoustic wave filter 1 shown in FIG. 14. As shown in FIG. 14, series resonators SR1, SR2, and SR3 are connected in series between terminal 2 and terminal 3. Parallel resonators PR1 and PR2 are connected in parallel between these series resonators SR1, SR2, and SR3 and ground.

In the ladder-type acoustic wave filter 1, a capacitive element C1 is connected in parallel to SR1, thereby constituting a series resonant circuit 4. A capacitive element C2 is connected in parallel to the parallel resonator PR1, thereby constituting a parallel resonant circuit 5. By applying the resonant circuit 100 (or the resonant circuit 100A) described above to such series resonant circuit 4 or parallel resonant circuit 5, for example, the series resonator SR1 may be the resonator 10 and the capacitive element C1 may be the interdigital capacitor 20 (or the interdigital capacitor 20A), thereby constituting the ladder-type acoustic wave filter 1.

Thus, by including the capacitive element C1 or C2 in the series resonant circuit 4 or the parallel resonant circuit 5, the steepness of the frequency characteristics of the series resonant circuit 4 or the parallel resonant circuit 5 can be increased. If the resonant circuits 100 and 100A according to the embodiment are applied thereto, a low-loss resonant circuit is obtained by the low-loss interdigital capacitor (20 or 20A), so that a ladder-type acoustic wave filter 1 with low loss can be configured.

In the above embodiment, the present invention can also be applied to resonant circuits other than ladder-type acoustic wave filters.

It should be noted that the term “same” for the pitch P includes ±0.05% as a manufacturing tolerance. In addition, the drawings used in the above description are schematic, and the dimensions and ratios in the drawings do not necessarily match those of actual products.

Although the present invention has been described above, in implementing the present invention as an acoustic wave device and an interdigital capacitor, various modifications and additions can be made without departing from the gist of the present invention, and are not limited to the embodiments described above. The above is merely an embodiment of the present invention, and is not intended to limit the scope of the present invention. Any equivalent structural or process modifications made based on the contents of the description and drawings of the present embodiment, or any direct or indirect applications in other related technical fields, shall be deemed to be included within the scope of protection of the present invention.

What is claimed is:

1. An acoustic wave device, comprising:
a piezoelectric substrate;
a resonator formed on the piezoelectric substrate and configured to excite a wave of a main mode; and
an interdigital capacitor formed on the piezoelectric substrate and comprising a pair of comb-shaped electrodes having electrode fingers interdigitated with each other;
wherein the interdigital capacitor has the electrode fingers arranged with a non-uniform pitch so as to excite neither waves of modes other than the main mode nor a wave of the main mode.

2. The acoustic wave device according to claim 1, wherein the interdigital capacitor has electrode finger pitches that gradually increase from one end to the other in a direction orthogonal to an extending direction of the electrode fingers.

3. The acoustic wave device according to claim 1, wherein the interdigital capacitor is divided into a plurality of sections, from a first section to an n-th section where n is an integer greater than or equal to 3, in a direction orthogonal to an extending direction of the electrode fingers, each section having a different electrode finger pitch;
wherein, within the same section among the plurality of sections, a plurality of electrode fingers are arranged with a uniform pitch, and
wherein the pitch of the electrode fingers gradually increases from the first section to the n-th section.

4. The acoustic wave device according to claim 3, wherein the pitch of the electrode fingers increases by 10% or more from the first section to the n-th section.

5. The acoustic wave device according to claim 3, wherein n is an integer greater than or equal to 5, and wherein a per-section pitch increase rate of the electrode finger pitch between successive sections is greater than or equal to 5%.

6. The acoustic wave device according to claim 3, wherein n is an integer greater than or equal to 9, and wherein a per-section pitch increase rate of the electrode finger pitch between successive sections is greater than or equal to 2.5%.

7. The acoustic wave device according to claim 1, wherein the resonator formed on the piezoelectric substrate and configured to excite a wave of the main mode includes IDT electrode fingers, and the IDT electrode fingers of the resonator and the electrode fingers of the interdigital capacitor are arranged such that their extending directions are non-orthogonal.

8. The acoustic wave device according to claim 7, wherein the IDT electrode fingers of the resonator and the electrode fingers of the interdigital capacitor are arranged such that their extending directions are parallel.

9. The acoustic wave device according to claim 7, wherein the IDT electrode fingers of the resonator and the electrode fingers of the interdigital capacitor are arranged at an inclination.

10. The acoustic wave device according to claim 7, wherein the resonator and the interdigital capacitor are connected in parallel.

11. A ladder-type acoustic wave filter, comprising a plurality of series resonators, a plurality of parallel resonators, a first capacitive element, a first terminal, a second terminal, a third terminal and a ground terminal, wherein the series resonators are connected in series between the second terminal and the third terminal, and the parallel resonators are connected in parallel between the series resonators and the ground terminal, and the first capacitive element is connected in parallel to one of the series resonators thereby constituting a series resonant circuit;
wherein the first capacitive element is an interdigital capacitor formed on a piezoelectric substrate, the interdigital capacitor including a pair of comb-shaped electrodes having electrode fingers interdigitated with each other, and the interdigital capacitor has the electrode fingers arranged with a non-uniform pitch so as to excite neither waves of modes other than the main mode nor a wave of the main mode.

12. The ladder-type acoustic wave filter according to claim 11, further comprising a second capacitive element connected in parallel to one of the parallel resonators, thereby constituting a parallel resonant circuit.

13. The ladder-type acoustic wave filter according to claim 11, wherein the interdigital capacitor has electrode finger pitches that gradually increase from one end to the other in a direction orthogonal to an extending direction of the electrode fingers.

14. The ladder-type acoustic wave filter according to claim 11, wherein the interdigital capacitor is divided into a plurality of sections, from a first section to an n-th section where n is an integer greater than or equal to 3, in a direction orthogonal to an extending direction of the electrode fingers, each section having a different electrode finger pitch;
wherein, within the same section among the plurality of sections, a plurality of electrode fingers are arranged with a uniform pitch, and
wherein the pitch of the electrode fingers gradually increases from the first section to the n-th section.

15. The ladder-type acoustic wave filter according to claim 14, wherein the pitch of the electrode fingers increases by 10% or more from the first section to the n-th section.

16. The ladder-type acoustic wave filter according to claim 11, wherein the resonator formed on the piezoelectric substrate and configured to excite a wave of the main mode includes IDT electrode fingers, and the IDT electrode fingers of the resonator and the electrode fingers of the interdigital capacitor are arranged such that their extending directions are non-orthogonal.

17. An interdigital capacitor formed on a piezoelectric substrate, the interdigital capacitor comprising a pair of comb-shaped electrodes having electrode fingers interdigitated with each other,
wherein the interdigital capacitor has the electrode fingers arranged with a non-uniform pitch so as to excite neither waves of modes other than the main mode nor a wave of the main mode.

18. The interdigital capacitor according to claim 17, wherein the interdigital capacitor has electrode finger pitches that gradually increase from one end to the other in a direction orthogonal to an extending direction of the electrode fingers.

19. The interdigital capacitor according to claim 17, wherein the interdigital capacitor is divided into a plurality of sections, from a first section to an n-th section where n is an integer greater than or equal to 3, in a direction orthogonal to an extending direction of the electrode fingers, each section having a different electrode finger pitch;
wherein, within the same section among the plurality of sections, a plurality of electrode fingers are arranged with a uniform pitch, and
wherein the pitch of the electrode fingers gradually increases from the first section to the n-th section.

20. The interdigital capacitor according to claim 17, wherein the pitch of the electrode fingers increases by 10% or more from the first section to the n-th section.
